(19) United States
(12) Patent Application Publication
(10) Pub. No.: US 2017/0337967 A1
(43) Pub. Date: Nov. 23, 2017

(54) MEMORY DEVICES AND METHODS FOR OPERATING THE SAME

(71) Applicant: Samsung Electronics Co., Ltd., Suwon-si (KR)

(72) Inventors: Amit BERMAN, Ramat Gan (IL); Jun Jin Kong, Yongin-si (KR); Uri Beitler, Ramat Gan (IL)

(73) Assignee: Samsung Electronics Co., Ltd., Suwon-si (KR)

(21) Appl. No.: 15/156,956

(22) Filed: May 17, 2016

(51) Int. Cl. G11C 11/56

(52) U.S. Cl. CPC G11C 11/5628; G11C 11/5642

(57) ABSTRACT

A memory device includes a memory including memory cells, each of the memory cells being configured to store multiple bits of data. The memory device includes a controller configured to map the levels of the memory cells to bits such that a first half of the levels have a bit with a first binary value in a desired bit position and a second half of the levels have a bit with a second binary value in the desired bit position. The first half of the levels are a first group of consecutive levels, and the second half of the levels are a second group of consecutive levels. The controller is configured to generate a distribution for writing the data to the memory cells based on the mapping, and write the data to the memory cells based on the determined distribution.

### BACKGROUND

### Field

At least one example embodiment relates to memory devices and/or methods of operating memory devices.

### Description of Related Art

Random read access time is an important performance parameter in nonvolatile memory devices such as solid state disk (SSD) devices, embedded multimedia card (eMMC) devices, etc. The increase in storage capacity of these memory devices has created a desire for higher write and read bandwidth so that the memory devices can be used more effectively. Sequential operations may be improved by extending the length of a word line to include more memory cells or by including additional layers of memory cells. However, these methods result in products where the number of cells in a word line (i.e., page size) exceeds a system's logical sectorsize. For example, a 3 bit/cell memory array may store data in 8 KB pages while the operating system reads data in 4 KB sectors. While executing a page read operation, the number of sensing operations is the same for both the page and the sector.

In the following example, allow W_{Z} to be the number of cells per word line and S_{Z} the amount of bits in a sector. In typical operating systems, S_{Z}=4 KB. Further, allow N_{S} to be the number of sectors per word line. When considering L levels per cell:

$${N}_{S} = \frac{{W}_{Z}}{{S}_{Z}} {log}_{2} ( L ) \qquad Equation 1$$

Allow NSR to be the average amount of reference voltages (or sensing operations) desired for a sector read operation (e.g., an array-to-buffer sector read operation). Given {S₁, S₂, . . . , S_{N}} sectors per word line, and denoting N_{REF}(Si) as the number of sensing operations to read sector Si, the expected reference voltages (or sensing operations) per sector read operation is:

$${N}_{SR} = \frac{{\sum }_{i} {N}_{REF} ( {S}_{i} )}{{N}_{S}} \qquad Equation 2$$

Allow t_{SR} to be the expected duration of a sector read operation. This time consists of a sensing time (e.g., the amount of reference voltages multiplied by a single reference duration, denoted as t_{REF}) and a sector output operation. Since each sector is read with a different number of reference voltages, the expected duration tsR is the sum over all sectors in a word line divided by the number of references:

$${t}_{SR} = \frac{{\sum }_{i} [ {N}_{REF} ( {S}_{i} ) \cdot {t}_{REF} + {S}_{Z} {t}_{RC} ]}{{N}_{S}} \qquad Equation 3$$

FIG. 1 shows a conventional levels-to-bits mapping scheme for writing data to 3 bit/cell memory cells and a reading scheme for reading the data from the memory cells. In FIG. 1, the page size (or word line length) is 9 KB and the sector size (or size in which data is written and read) is 4.5 KB. The levels-to-bits mapping FIG. 1 shows a bit mapping for levels 0-7 in accordance with a Gray code. The levels 0-7 may correspond to the eight different possible voltage threshold distributions for memory cells of the 3 bit/cell memory. Sector data is programmed to the memory cells according to this level-to-bits mapping scheme. During a read operation, reference voltages Ref₀₋₁ to Ref₆₋₇ are applied to a most significant hit MSB page of data. including sectors 1 and 2, a central significant bit (CSB) page of data including sectors 4 and 5, and a least significant bit (LSB) page of data including sectors 5 and 6 in the manner shown in FIG. 1. Using Equation 2 above, the average number of sensing operations (i.e., a number of applications of reference voltages) per sector is NSR=(2+2+3+3+2+2)/6=2.33 sensing operations/sector.

Because the number of sensing operations is related to the duration of a sector read operation and power consumed by the memory controller, reducing the amount of sensing operations per sector read operation is desired.

### SUMMARY

According to at least one example embodiment, a memory device includes a memory including memory cells, each of the memory cells being configured to store multiple bits of data. The memory device includes a controller configured to map the levels of the memory cells to bits such that a first half of the levels have a bit with a first binary value in a desired bit position and a second half of the levels have a bit with a second binary value in the desired bit position. The first half of the levels are a first group of consecutive levels, and the second half of the levels are a second group of consecutive levels. The first binary value is opposite the second binary value. The controller may generate a distribution for writing the data to the memory cells based on the mapping, and write the data to the memory cells based on the determined distribution.

According to at least one example embodiment, the controller is configured to map such that the consecutive levels of the first and second groups differ by a single bit.

According to at least one example embodiment, the controller is configured to generate the distribution by counting a number of the memory cells where the desired bit position in at least one page of the distribution is the second binary value.

According to at least one example embodiment, the controller is configured to generate the distribution by padding the at least one page with a memory cell associated with a level that has the second binary value in the desired bit position if the counted number of memory cells is less than a sector size in which the data is readable.

According to at least one example embodiment, the controller is configured to generate the distribution by padding the at least one page with a memory cell associated with a level that has the first binary value in the desired bit position if the counted number of memory cells is greater than a sector size in which the data is readable.

According to at least one example embodiment, the controller is configured to write the data by writing a first sector of bits of the data to memory cells where the generated distribution indicates that the desired bit position has the first binary value, and writing a second sector of bits of the data to memory cells where the generated distribution indicates that the desired bit position has the second binary value.

According to at least one example embodiment, the memory is a nonvolatile flash memory.

According to at least one example embodiment, the nonvolatile flash memory is a three-dimensional memory array.

According to at least one example embodiment, a memory device includes a memory including memory cells, each of the memory cells storing multiple bits of data. The memory device includes a controller configured to receive a request to read the memory cells. The controller reads the memory cells by applying a first reference voltage to the memory cells. The first reference voltage is a reference voltage from among a plurality of reference voltages used to determine program states of the memory cells, and a number of the plurality of reference voltages is equal to a number of the program states for each of the memory cells. The controller reads the memory cells by applying remaining ones of the plurality of reference voltages based on an address of the request such that less than all of the plurality of reference voltages are used to read the multiple bits of data.

According to at least one example embodiment, the first reference voltage is a median ference voltage from among the plurality of reference voltages.

According to at least one example embodiment, the controller is configured to determine whether the request to read the memory cells is for a first or second sector associated with a least significant bit of the multiple bits by checking an address of the request.

According to at least one example embodiment, if the address indicates a request to read the first sector, the controller is configured to ignore memory cells in the first sector that have a mapping value of a first binary value in a desired bit position and set the first sector of memory cells as the memory cells with a mapping value of a second binary mapping value in the desired bit position.

According to at least one example embodiment, the controller is configured to apply second and third reference voltages to the memory cells in the first sector and mark all memory cells in the first sector that are below the second reference voltage and above the third reference voltage with the first binary value.

According to at least one example embodiment, the second and third reference voltages are less than the first reference voltage.

According to at least one example embodiment, the controller is configured to output the first sector of data.

According to at least one example embodiment, if the controller determines that the read request is for the second sector, the controller is configured to ignore memory cells in the second sector with a mapping value a first binary value in the desired bit position and set memory cells of the second sector as the memory cells with a mapping value of a second binary value in the desired bit position.

According to at least one example embodiment, the controller is configured to apply fourth and fifth reference voltages to the memory cells in the second sector and mark all memory cells in the second sector below the fourth reference voltage and above the fifth reference voltage with the first binary value.

According to at least one example embodiment, the fourth and fifth reference voltages are greater than the first reference voltage.

According to at least one example embodiment, the controller is configured to output the second sector of data.

According to at least one example embodiment, a method includes mapping levels of memory cells to bits such that a first half of the levels have a bit with a first binary value in a desired bit position and a second half of the levels have a bit with a second binary value in the desired bit position. The first half of the levels are a first group of consecutive levels, and the second half of the levels are a second group of consecutive levels. The first binary value is opposite the second binary value, and each of the memory cells is configured to store multiple bits of data. The method includes generating a distribution for writing the data to the memory cells based on the mapping, and writing the data to the memory cells based on the determined distribution.

### BRIEF DESCRIPTION OF DRAWINGS

The above and other aspects and features of the inventive concepts will become more apparent by describing in detail example embodiments thereof with reference to the attached drawings, in which:

FIG. 1 shows a conventional levels-to-bits mapping scheme for writing data to 3 bit/cell memory cells and a reading scheme for reading the data from the memory cells.

FIG. 2A illustrates a memory device according to at least one example embodiment.

FIG. 2B is an example structure of the controller in FIG. 2A.

FIG. 3A illustrates a method of writing data to a memory according to at least one example embodiment.

FIG. 3B illustrates a method of generating a distribution and writing pages of data to a memory according to at least one example embodiment.

FIG. 3C illustrates an example mapping of the levels-to-bits and an example of how pages of data are stored in a memory according to at least one example embodiment.

FIG. 3D illustrates an example of how pages of data are stored in a memory according to at least one example embodiment.

FIGS. 3E-3G illustrate example mappings of levels-to-bits according to at least one example embodiment

FIGS. 4A and 4B illustrate a method for reading data from a memory according to at least one example embodiment.

### DETAILED DESCRIPTION OF EXAMPLE EMBODIMENTS

Inventive concepts rill now be described more fully with reference to the accompanying drawings, in which example embodiments of are shown. These example embodiments are provided so that this disclosure will be thorough and complete, and will fully convey inventive concepts of to those skilled in the art. Inventive concepts may be embodied in many different forms with a variety of modifications, and a few embodiments will be illustrated in drawings and explained in detail. However, this should not be construed as being limited to example embodiments set forth herein, and rather, it should be understood that changes may be made in these example embodiments without departing from the principles and spirit of inventive concepts, the scope of which are defined in the claims and their equivalents. Like numbers refer to like elements throughout. In the drawings, the thicknesses of layers and regions are exaggerated for clarity.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

Unless specifically stated otherwise, or as is apparent from the discussion, terms such as “processing” or “computing” or “calculating” or “determining” or “displaying” or the like, refer to the action and processes of a computer system, or similar electronic computing device, that manipulates and transforms data represented as physical, electronic quantities within the computer system's registers and memories into other data similarly represented as physical quantities within the computer system memories or registers or other such information storage, transmission or display devices.

Specific details are provided in the following description to provide a thorough understanding of example embodiments. However, it will be understood by one of ordinary skill in the art that example embodiments may be practiced without these specific details. For example, systems may be shown in block diagrams so as not to obscure exam embodiments in unnecessary detail. In other instances, well-known processes, structures and techniques may be shown without unnecessary detail in order to avoid obscuring example embodiments.

In the following description, illustrative embodiments will be described with reference to acts and symbolic representations of operations (e.g., in the form of flow charts, flow diagrams, data flow diagrams, structure diagrams, block diagrams, etc.) that may be implemented as program modules or functional processes include routines, programs, objects, components, data structures, etc., that perform particular tasks or implement particular abstract data types and may be implemented using existing hardware in existing electronic systems (e.g., electronic imaging systems, image processing systems, digital point-and-shoot cameras, personal digital assistants (PDAs , smartphones, tablet personal computers (PCs), laptop computers, etc.). Such existing hardware may include one or more Central Processing Units (CPUs), digital signal processors (DSPs), application-specific-integrated-circuits (ASICs), field programmable gate arrays (FPGAs) computers or the like.

Although a flow chart may describe the operations as a sequential process, many of the operations may be performed in parallel, concurrently or simultaneously. In addition, the order of the operations may be re-arranged. A process may be terminated when its operations are completed, but may also have additional steps not included in the figure. A process may correspond to a method, function, procedure, subroutine, subprogram, etc. When a process corresponds to a function, its termination may correspond to a return of the function to the calling; function or the main function.

As disclosed herein, the term “storage medium”, “computer readable storage medium” or “non-transitory computer readable storage medium” may represent one or more devices for storing data, including read only memory (ROM), random access memory (RAM), magnetic RAM, core memory, magnetic disk storage mediums, optical storage mediums, flash memory devices and/or other tangible or non-transitory machine readable mediums for storing information. The term “computer-readable medium” may include, but is not limited to, portable or fixed storage devices, optical storage devices, and various other tangible or non-transitory mediums capable of storing, containing or carrying instruction(s) and/or data.

Furthermore, example embodiments may be implemented by hardware, software, firmware, middleware, microcode, hardware description languages, or any combination thereof. When implemented in software, firmware, middleware or microcode, the program code or code segments to perform the necessary tasks may be stored in a machine or computer readable medium such as a computer readable storage medium. When implemented in software, a processor or processors may be programmed to perform the necessary tasks, thereby being transformed into special purpose processor(s) or computer(s).

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “includes”, “including”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “and/or” includes any and all combinations of one or more of the associated listed items. Expressions such as “at least one of,” when preceding a list of elements, modify the entire list of elements and do not modify the individual elements of the list.

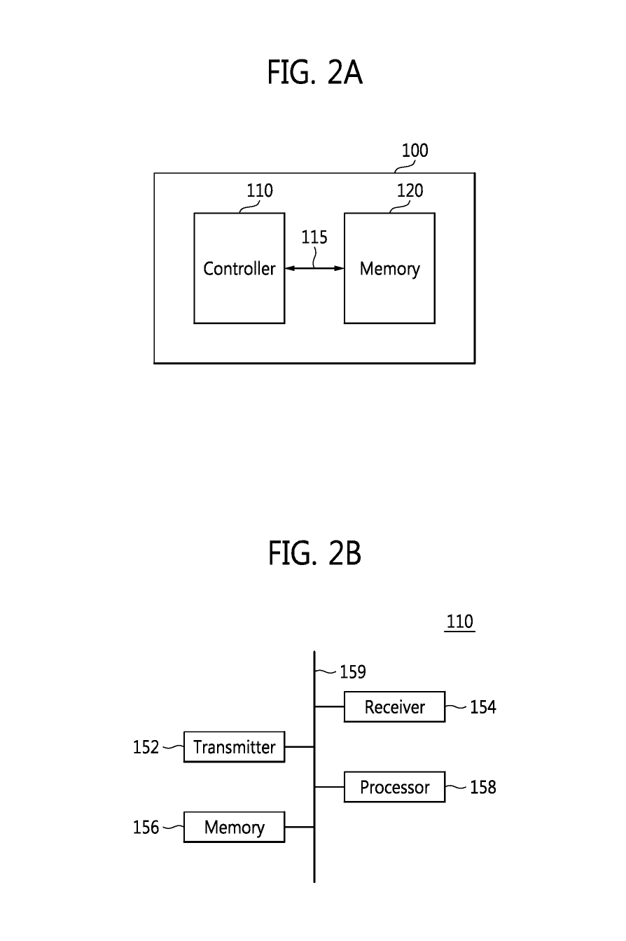

FIG. 2A illustrates a memory device according to at least one example embodiment.

As shown in FIG. 2A, a memory device 100 includes a controller 110 in communication with a memory 120 via a bus 115. The memory 120 may be a nonvolatile memory, for example, a NAND flash memory. The memory 120 may be a three-dimensional memory array (e.g., a vertical NAND (VNAND) flash memory). The memory device 100 may be embodied as a solid state disk (SSD) drive, an embedded multimedia card (eMMC) device, etc. The memory 120 may be a multilevel cell (MLC) memory capable of storing multiple bits of data per memory cell, for example, 2-bits per cell, 3-bits per cell, 4-bits per cell, etc.

FIG. 2B is an example structure f the controller in FIG. 2A.

FIG. 2B is a diagram illustrating an example structure of the controller 110 according to an example embodiment. Referring to FIG. 2B, the controller 110 may include, for example, a data bus 159, a transmitter 152, a receiver 154, a memory 156, and a processor 158.

The transmitter 152, receiver 154, memory 156, and processor 158 may send data to and/or receive data from one another using the data bus 159. The transmitter 152 is a device that includes hardware and any necessary software for transmitting signals including, for example, data signals and control signals to the memory 120 and/or a host (not shown).

The receiver 154 is a device that includes hardware and any necessary software for receiving signals including, for example, data signals and control signals to and from the memory 120 and a host (not shown).

The memory 156 may be any device capable of storing data including magnetic storage, flash storage, etc.

The processor 158 may be any device capable of processing data including, for example, a special purpose processor configured to carry out specific operations based on input data, or capable of executing instructions included in computer readable code stored on the memory 156. For example, it should be understood that the modifications and methods described below may be stored on the memory 156 and implemented by the processor 158.

Further, it should be understood that the below modifications and methods may be carried out by one or more of the above described elements of the controller 110. For example, the receiver 154 may carry out steps of “receiving,” “acquiring,” and the like; transmitter 152 may carry out steps of “transmitting,” “outputting,” “sending” and the like; processor 158 may carry out steps of “determining,” “generating”, “correlating,” “calculating,” and the like; and memory 156 may carry out steps of “storing,” “saving,” and the like.

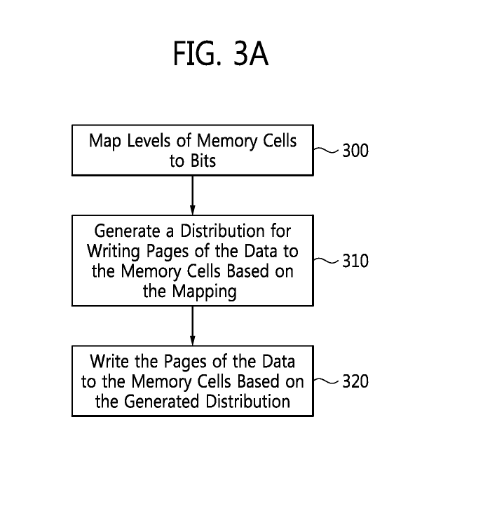

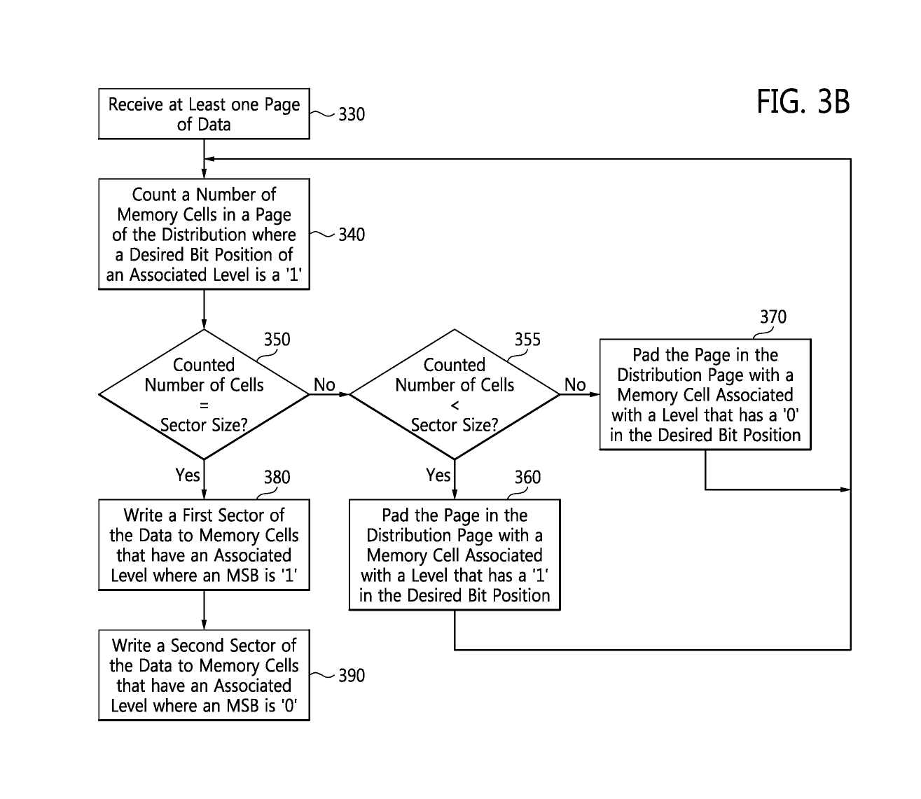

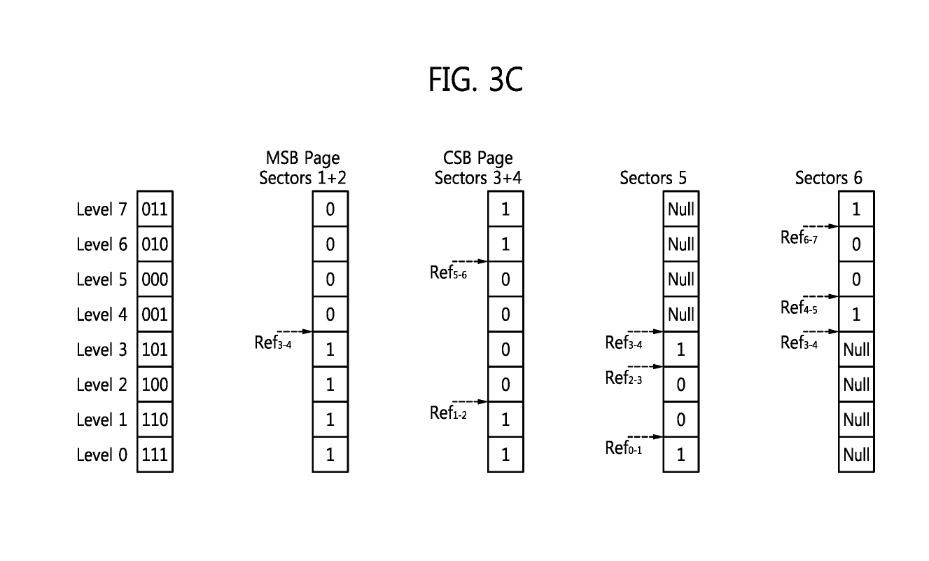

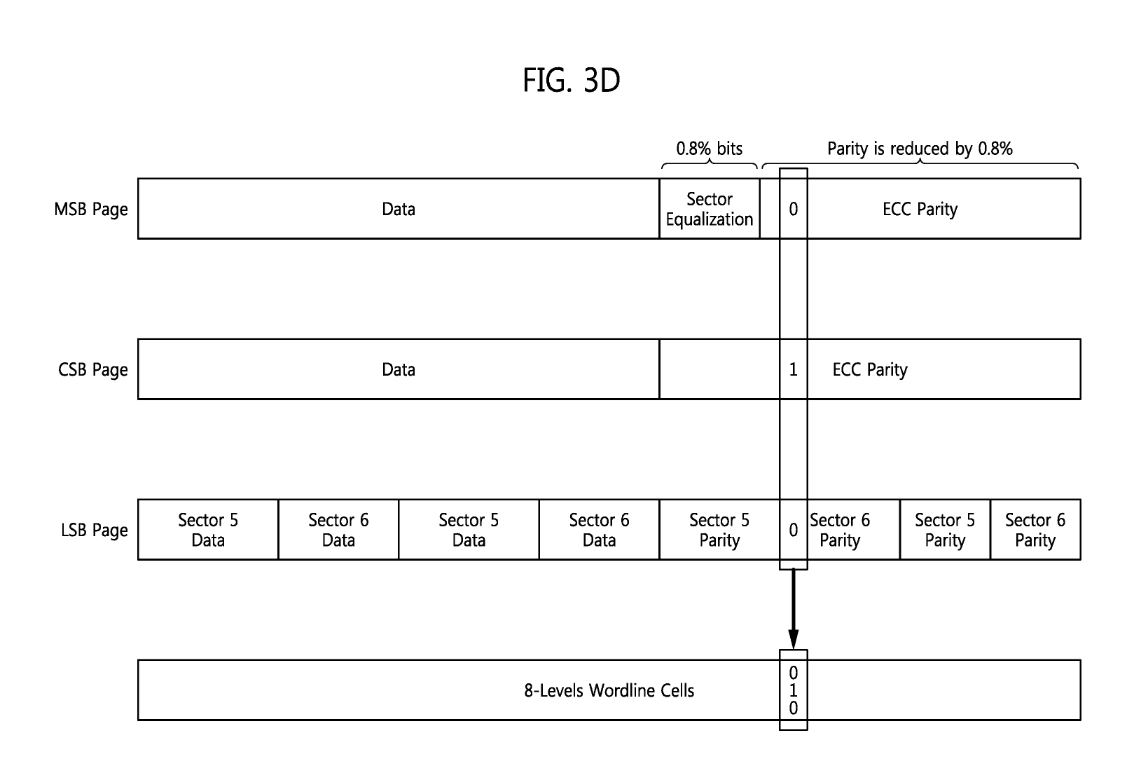

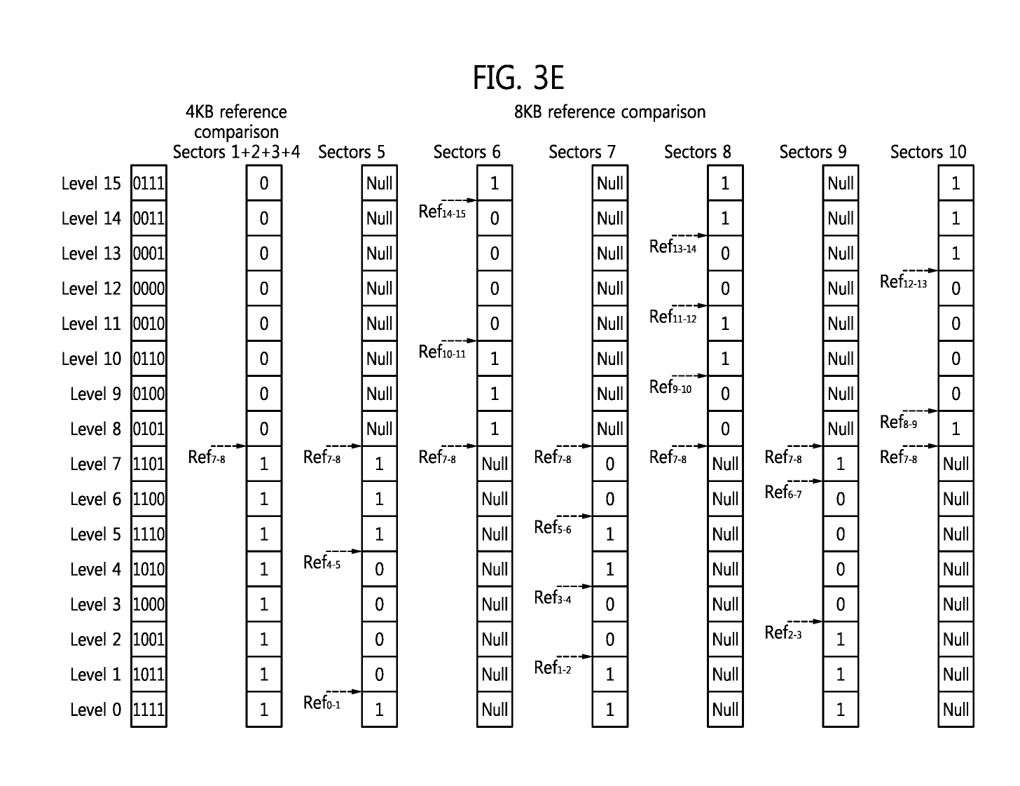

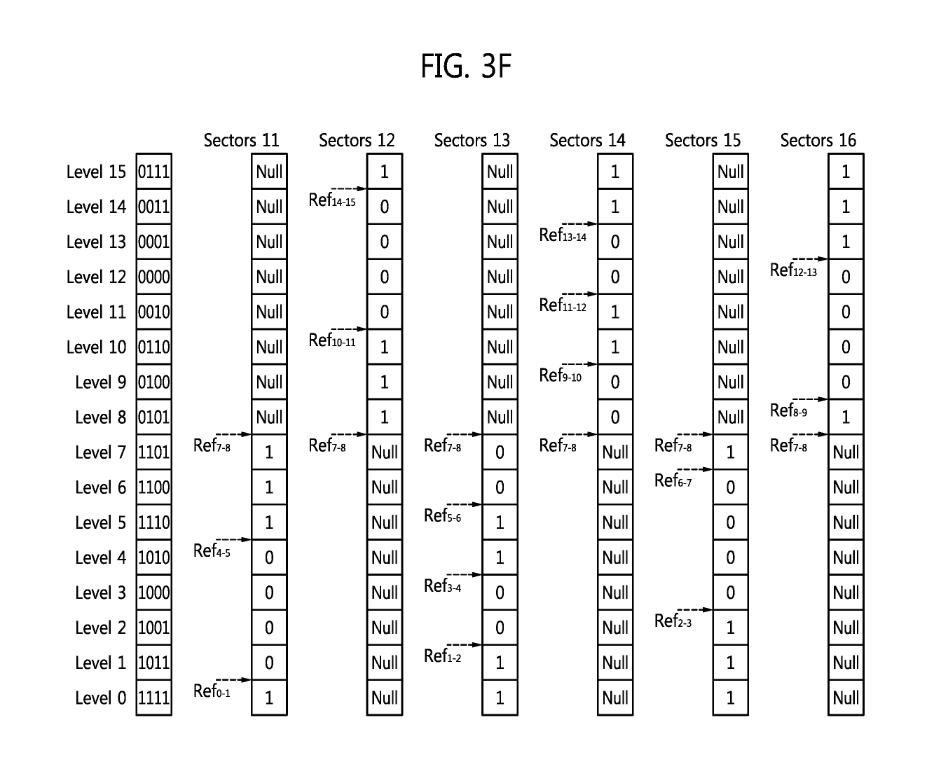

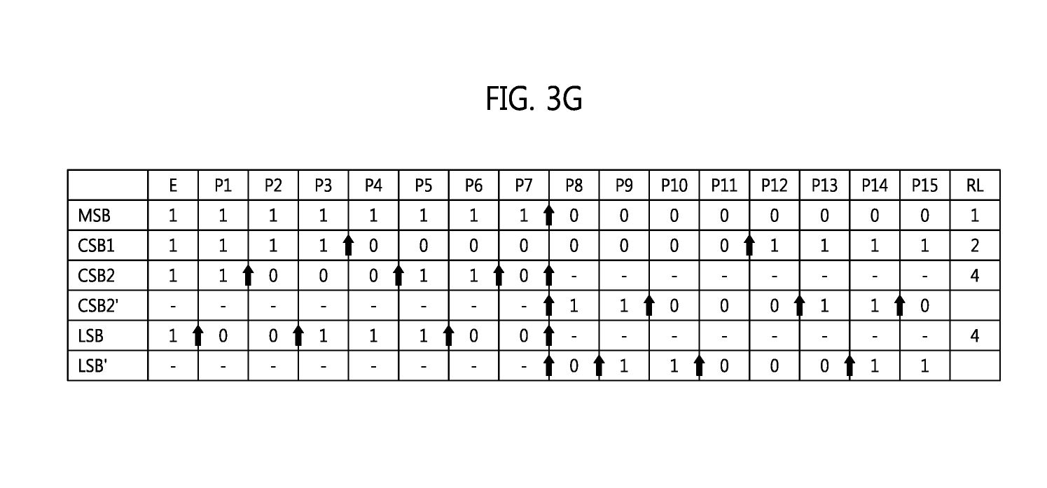

FIG. 3A illustrates a method of writing data to a memory according to at least one example embodiment. FIG. 3B illustrates a method of generating a distribution and writing pages of data to a memory according to at least one example embodiment. FIG. 3C illustrates an example mapping of the levels to bits and an example of how pages of data are stored in a memory according to at least one example embodiment. FIG. 3D illustrates an example of how pages of data are stored in a memory according to at least one example embodiment. FIGS. 3A-3D are discussed with respect to an example where the memory 120 is a 3 bit/cell memory array with a 9 KB page size, and a sector size is 4.5 KB.

In operation 300, the controller 110 maps levels of memory cells to bits that correspond to each level. The levels may correspond to program states of the memory cells in memory 120. Thus, in the 3 bit/cell memory array, there are eight levels (or program states) for the memory cells. In an example, the controller 110 maps the levels to the bits such that a first half of the levels have a bit with a first binary value in a desired bit position and a second half of the levels have a bit with a second binary value in the desired bit position. The first half of the levels may be a first group of consecutive levels the second half of the levels may be a second group of consecutive levels. The first binary value may be opposite the second binary value. The controller 110 performs the mapping in operation 300 such that the consecutive levels of the first and second groups differ by a single hit so that the mapping adheres to a Gray code (see most left column of FIG. 3C for an example mapping of levels-to-bits that satisfy the above conditions and adhere to the Gray code).

In operation 310, the controller 110 generates a distribution for writing pages of data to the memory cells based on the mapping in operation 300. For example, the controller 110 generates the distribution based on the first binary values, the second binary values, and the desired hit position. The controller 110 may generate the distribution such that each level (or program state) is associated with a substantially same number of memory cells in a word line, which may reduce unequal cell degradation. Operation 310 is described in further detail below with reference to FIG. 3B.

In operation 320, the controller 110 writes the pages of data to the memory cells of memory 120 based on the generated distribution. For example, the controller 110 may write a first sector of bits of the data to memory cells where the generated distribution indicates that the desired bit position has the first binary value. The controller 110 may write a second sector of bits of the data to memory cells where the determined distribution indicates that the desired bit position has the second binary value. As discussed in detail below with reference to FIGS. 3B and 3C, the first and second sectors may be associated with a LSB page(s) of data (i.e., sectors 5 and 6 in FIG. 3C). Operations 310 and 320 may correspond to the pseudocode in Algorithm 1 below, and are described in more detail with reference to FIGS. 3B and 3C below.

Algorithm 1: 8-Levels LSB page (Sectors 5 + 6) Encoding

```
Input: {MSB and CSB pages}
  (1) MSB1 ← Count cells in distribution where (MSB = 1)
  (2) If MSB1<Sector Size
  (2.1) Add (MSB = 1 and CSB = 1) to pad cells in distribution until
  (MSB1 + add) equals Sector size
Else if MSB1>Sector Size
  (2.2) Add (MSB = 0 and CSB = 1) to pad cells in distribution until
  (MSB1 − add) equals Sector size
  (3) Store Sector 5 bits in cells where (MSB = 1)
  (4) Store Sector 6 bits in cells where (MSB = 0)
```

FIG. 3B illustrates operation 320 in further detail. Here, the operations of FIG. 3B may correspond to operations for writing a least significant bit (LSB) page of data to the memory 120 (assuming the memory 120 is a 3 bit/cell memory array).

In operation 330, the controller 110 receives at least one page of the pages of data to be programed to the memory 120. For example, the controller 110 receives most significant bit (MSB) and central significant bit (CSB) pages of data. As mentioned with respect to operation 310, each level (or program state) is associated with a substantially same number of memory cells in a word line (or a page) of the generated distribution.

Thus, in operation 340, the controller 110 counts a number of the memory cells in a page of the distribution determined in operation 310 where the desired bit position of an associated level is the second binary value. For example, if the desired bit position is the MSB, the controller 110 counts a number of memory cells having an associated level where the MSB is a ‘1.’

In operation 350, the controller 110 determines whether the counted number of memory cells is equal to a sector size in which data is written and read by the controller 110. If not, the controller 110 determines whether the counted number of memory cells is less than the sector size in operation 355.

If the counted number of memory cells is less than the sector size, then in operation 360, the controller 110 pads the page in the distribution from operation 310 with a memory cell associated with a level that has the second binary value (or ‘1’) in the desired bit position (e.g., the MSB position) and in a bit position adjacent to the desired bit positon (e.g., the CSB position), and returns to operation 340.

If, in operation 355, the controller 110 determines that the counted number of memory cells is not less than the sector size (i.e., that the counted number of memory cells is greater than the sector size), then in operation 370, the controller 110 pads the page in the distribution from operation 310 with a memory cell associated with a level that has the first binary value (or ‘0’) in the desired bit positon (e.g., the MSB position) and the second binary value (or ‘1’) in an adjacent bit positon (e.g., the CSB position), and returns to operation 340.

If, in operation 350, the controller 110 determines that the counted number of memory cells equals the sector size, the controller 110 performs operation 380. In this example for a 3 bit/cell memory array with a 9 KB page size and a 4.5 KB sector size, the controller 110, in operation 380, writes a first sector of bits of a LSB page (e.g., sector 5 bits) to memory cells that have an associated level where an MSB is the second binary value (or ‘1’). In operation 390, the controller 110 writes a second sector of bits of the LSB page (e.g., sector 6 bits) to memory cells where an associated level where an MSB is the first binary value (or ‘0’).

FIG. 3C illustrates an example mapping of the levels-to-bits from operation 300 in the left-most column. For example, FIG. 3C shows a mapping of levels to bits once the controller 110 has performed operation 300 for, in this case, a 3 bit/cell memory array. Here, the desired bit position is the most significant bit (MSB), the first binary value is ‘0,’ and the second binary value is ‘1.’ The first group of consecutive levels includes levels 0 to 3 and the second group of consecutive levels includes levels 4-7. Levels 0-7 may correspond to eight different program states used to store the data. In FIG. 3C, level 0 is mapped to ‘111,’ level 1 is mapped to ‘110,’ level 2 is mapped to ‘100,’ level 3 is mapped to ‘101,’ and so on. However, example embodiments are not limited to the mapping shown in FIG. 3C. For example, mapping may be carried where the desired bit position is different than the MSB (e.g., the least significant bit). This determination may be a design parameter based on empirical evidence.

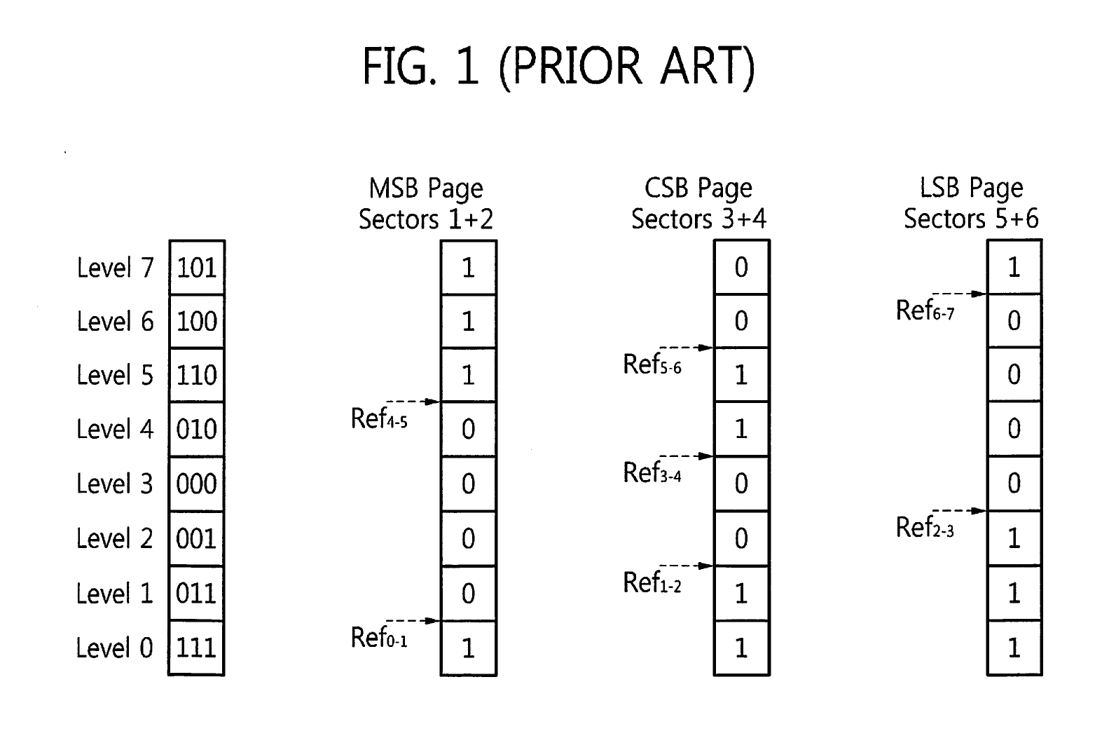

FIG. 3C also illustrates how sectors 1-6 are stored in the memory 120 in accordance with the operations of FIG. 3A and 3B. In FIG. 3C, sector 1 and 2 bits are stored on the MSB page and sector 3 and 4 bits are stored on the CSB page. However, unlike FIG. 1, sector 5 and 6 bits (for the LSB page) have been stored in accordance with the operations of FIGS. 3B. That is, sector 5 bits are stored to memory cells where the MSB for an associated level is ‘1’ and sector 6 bits are stored to memory cells where the MSB for an associated level is ‘0.’

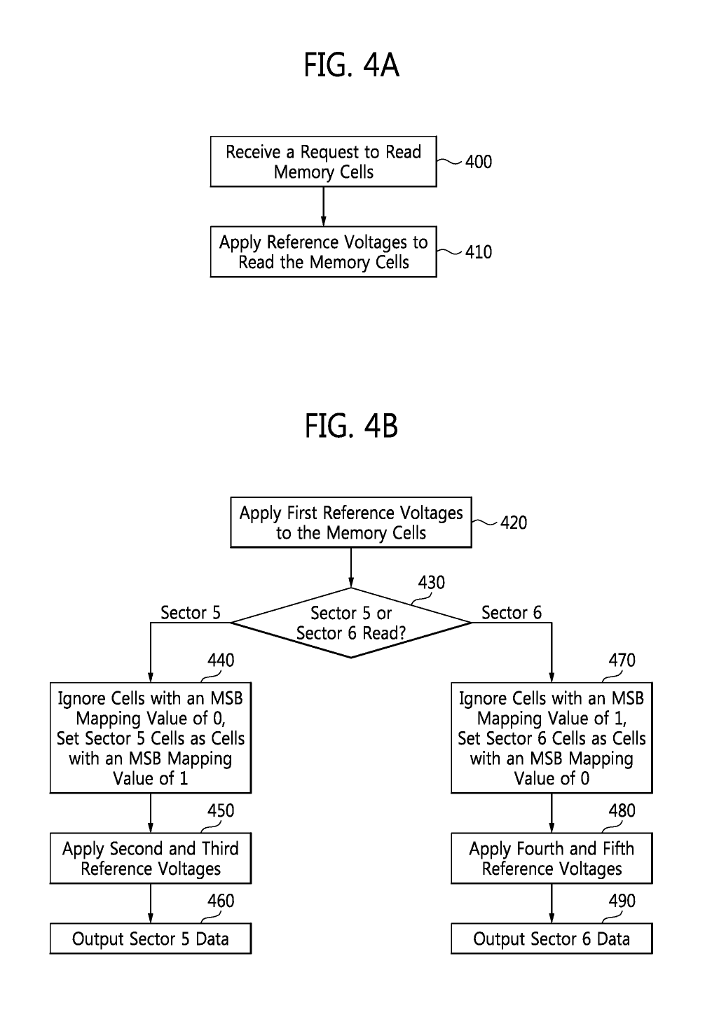

FIG. 3C further illustrates reference voltages Ref₀₋₁, Ref₁₋₂, etc. for reading the data from the memory 120. The reading operation is discussed in more detail below with reference to FIGS. 4A and 4B.

FIG. 3D illustrates an example of how pages of data are stored in the memory 120 according to at least one example embodiment. FIG. 3D shows that the MSB, CSB and LSB pages have data portions and parity portions. The parity portions may be used for error code correction (ECC). As shown in FIG. 3D, the MSB page includes an additional portion reserved for sector equalization which allows for padding memory cells as described above with respect to FIG. 3B. According to at least one example embodiment, a size of the parity portion of the MSB page may be reduced by 0.8% in order to allow for 0.8% for the sector equalization portion. This is possible because there is only one position of potential error for sectors of the MSB page with reference voltage Ref₃₋₄. Thus, the MSB page may be allowed to have weaker error protection by reducing the size of the parity portion.

FIGS. 3E-3G illustrates examples of a levels-to-bits mapping for an example in which the memory 120 is a 4-bit-per-cell memory that includes 16 KB word lines, which are readable and writable in 4 KB sectors. The example mappings shown in FIGS. 3E-3G are generated in accordance with the operations of 3A and 3B where the MSB is the desired bit position. In FIGS. 3E-3F, sectors 5-10 are stored in 8 KB chunks at even bit lines and sectors 11-16 are stored in 8 KB chunks at odd bit lines. The average number of read references per sector is 2.75. The example mappings in FIG. 3E-3G may balance errors because the variation is reduced between the number of read references per sector.

FIGS. 4A and 4B illustrate a method for reading data from a memory according to at least one example embodiment. As in FIGS. 3A-3C, FIGS. 4A and 4B are discussed with respect to an example where the memory 120 is a 3 bit/cell memory array with a 9 KB page size, and a sector size is 4.5 KB.

With reference to FIG. 4A, in operation 400, the controller 110 receives a request (e.g., from a host device, not shown) to read memory cells of memory 120. The memory cells may be storing multiple bits of data and have already been programmed with the data according to the operations and examples discussed above with reference to FIGS. 3A-3D. In operation 410, the controller 110 reads the memory cells by applying reference voltages from among a plurality of reference voltages. The plurality of reference voltages are used to determine program states (or levels) of the memory cells. Thus, a number of the plurality of reference voltages is equal to a number of the program states (or levels) for each of the memory cells. As discussed in further detail below, the controller 110 applies the plurality of reference voltages such that less than all of the plurality of reference voltages are used to read the multiple bits of data.

FIG. 4B illustrates an example method for reading sectors of a memory. For example, with reference to FIG. 3C and 4A, the operations of FIG. 4B further detail operation 410 to read sectors 5 and 6 of the memory 120. Data in sectors 1-4 may be read in accordance with the reference voltages shown FIG. 3C, where a reference voltage is applied (e.g., Ref₃₋₄) to sectors 1 and 2 and two additional reference voltages are applied to sectors 3 and 4 (e.g., Ref₁₋₂ and Ref₅₋₆). In view of the above, it may be said that the controller 110 applies remaining ones of the plurality of reference voltages based on an address of the sector such that less than all of the plurality of reference voltages are used to read the sector.

The operations in FIG. 4B may relate to Algorithm 2 below.

Algorithm 2: 8-Levels Read of Sector 5 or 6

```
(1) Read with Ref₃₋₄, mark cells above with 0 and below 1.
(2) If (Sector 5 Read)
  (2.1) Ignore cells with MSB value 0. Set Sector 5 cells as all cells with
  MSB value 1.
  (2.2) Read with Ref₂₋₃ and Ref₀₋₁. Mark all Sector 5 cells below Ref₂₋₃
  and above Ref₀₋₁ with a value 0.
  (2.3) Output Sector 5.
Else if (Sector 6 Read)
  (2.4) Ignore cells with MSB value 1. Set Sector 6 cells as all cells with
  MSB value 0.
  (2.5) Read with Ref₄₋₅ and Ref₆₋₇. Mark all Sector 6 cells below Ref₄₋₅
  and above Ref ₆₋₇ with a 1.
  (2.6) Output Sector 6.
```

In operation 420, the controller 110 applies a first reference voltage to the memory cells. The first reference voltage may be a median reference voltage from among the plurality of reference voltages since the memory cells were programmed in accordance with the mapping in operation 300. For example, with reference to FIG. 3C, the first reference voltage is Ref₃₋₄.

In operation 430, the controller 110 determines whether the request to read a sector in operation 400 is for a first or second sector (e.g., sector 5 or sector 6) associated with a least significant bit of the multiple bits by checking an address of the request.

If the address indicates a request to read the first sector (e.g., sector 5), the controller 110 proceeds to operation 440 to ignore memory cells with a mapping value of a first binary value in a desired bit position (e.g., an MSB mapping value of 0, the ignoring being indicated by “null” in FIG. 3C) and set the first sector (e.g., sector 5) of memory cells as the memory cells with a mapping value of a second binary value in the desired bit position (e.g., an MSB mapping value of 1).

In operation 450, the controller 110 applies second and third reference voltages to the memory cells and marks all memory cells of the first sector (e.g., sector 5) that are below the second reference voltage and above the third reference voltage with the first binary value (e.g., a value of 0). The second and third reference voltages may be less than the first reference voltage. For example, with reference to FIG. 3C, the second and third reference voltages may be Ref₂₋₃ and Ref₀₋₁, respectively.

In operation 460, the controller. 110 outputs the first sector of data (e.g., sector 5 data) to complete the read operation for the first sector.

If the controller 110 determines that the read request is for the second sector (e.g., the sector 6) data in operation 430, then the controller 110 proceeds to operation 470 to ignore memory cells with a mapping value of a first binary value in the desired hit position (e.g., an MSB mapping value of 1, indicated by “null” in FIG. 3C) and set memory cells of the second sector (e.g., sector 6 memory cells) as the memory cells with a mapping value of a second binary value (e.g., an MSB mapping value of 0).

In operation 480, the controller 110 applies fourth and fifth reference voltages to the memory cells of the second sector and marks all memory cells in the second sector below the fourth reference voltage and above the fifth reference voltage with the first binary value (e.g., a value of 1). The fourth and fifth reference voltages may be greater than the first reference voltage. For example, with reference to FIG. 3C, the fourth and fifth reference voltages may be Ref₄₋₅and Ref₆₋₇, respectively.

In operation 490, the controller 110 outputs data of the second sector (e.g., sector 6 data) to complete the read operation for the second sector.

Because the sector data were programmed to the memory cells according to the operations and examples shown in FIGS. 3A-3C, the controller 110 may use less than all eight of the reference voltages Ref₀₋₁ to Ref₆₋₇ during a read operation for the memory cells. For example, with reference to FIG. 3C, the controller 110 reads sectors 1 and 2 with a single reference voltage Ref₃₋₄ as a whole MSB page. Similarly, the controller 110 reads sectors 3 and 4 with two reference voltages Ref₁₋₂ and Ref₅₋₆ as a whole CSB page. However, unlike FIG. 1, the controller 110 may read sector 5 with three reference voltages Ref₀₋₁, Ref₂₋₃, and Ref₃₋₄, but without using reference voltage Ref₆₋₇. Similarly, the controller 110 reads sector 6 with reference voltages Ref₃₋₄, Ref₄₋₅, and Ref₆₋₇, but without using reference voltage Ref₀₋₁. In view of the above, it should be appreciated that the N_{SR} (or number of sensing operations per sector read operation in Equation 2) for reading sectors 5 or 6 is as follows:

$${N}_{SR} = \frac{{\sum }_{i} {N}_{REF} ( {S}_{i} )}{{N}_{S}} = \frac{1 + 1 + 2 + 2 + 3 + 3}{6} = 2 [ \frac{Refs}{Sector} ]$$

This is an improvement compared to the number of sensing operations per sector read operation for sectors 5 or 6 in FIG. 1.

In view of the above, it should be appreciated that a memory device writing and reading data in accordance with example embodiments may reduce the amount of time of a sector read operation and reduce power consumption of the memory device. Although example embodiments have been discussed with respect to a 3 bit/cell memory with a 9 KB page size and a 4.5 KB sector size, example embodiments are not limited thereto. For example, example embodiments of inventive concepts may apply to a 2 bit/ cell memory array, 4 bit/cell memory array (see FIGS. 3E-3G), etc.

While example embodiments have been shown and described above, it will be apparent to those skilled in the art that modifications and variations could be made without departing from the spirit and scope of the inventive concepts as defined by the appended claims.

1. A memory device, comprising:
a memory including memory cells, each of the memory cells being configured to store multiple bits of data; and
a controller configured to,
map levels of the memory cells to bits such that a first half of the levels have a bit with a first binary value in a desired bit position and a second half of the levels have a bit with a second binary value in the desired bit position, the first half of the levels being a first group of consecutive levels, the second half of the levels being a second group of consecutive levels, the first binary value being opposite the second binary value,
generate a distribution for writing the data to the memory cells based on the mapping, and
write the data to the memory cells based on the generated distribution by writing a first sector of bits of the data to memory cells where the generated distribution indicates that the desired bit position has the first binary value, and writing a second sector of bits of the data to memory cells where the generated distribution indicates that the desired bit position has the second binary value.

2. The memory device of claim 1, wherein the controller is configured to map such that the consecutive levels of the first and second groups differ by a single bit.

3. The memory device of claim 1, wherein the controller is configured to generate the distribution by counting a number of the memory cells where the desired bit position in at least one page of the distribution is the second binary value.

4. The memory device of claim 3, wherein the controller is configured to generate the distribution by padding the at least one page with a memory cell associated with a level that has the second binary value in the desired bit position if the counted number of memory cells is less than a sector size in which the data is readable.

5. The memory device of claim 3, wherein the controller is configured to generate the distribution by padding the at least one page with a memory cell associated with a level that has the first binary value in the desired bit position if the counted number of memory cells is greater than a sector size in which the data is readable.

6. (canceled)

7. The memory device of claim 1, wherein the memory is a nonvolatile flash memory.

8. The memory device of claim 7, wherein the nonvolatile flash memory is a three-dimensional memory array.

9. A memory device, comprising:
a memory including memory cells, each of the memory cells storing multiple bits of data; and
a controller configured to,
receive a request to read the memory cells;
read the memory cells by,
applying a first reference voltage to the memory cells, the first reference voltage being a reference voltage from among a plurality of reference voltages used to determine program states of the memory cells, a number of the plurality of reference voltages being equal to a number of the program states for each of the memory cells; and
applying remaining ones of the plurality of reference voltages based on an address of the request such that less than all of the plurality of reference voltages are used to read the multiple bits of data.

10. The memory device of claim 9, wherein the first reference voltage is a median reference voltage from among the plurality of reference voltages.

11. The memory device of claim 9, wherein controller is configured to determine whether the request to read the memory cells is for a first or second sector associated with a least significant bit of the multiple bits by checking an address of the request.

12. The memory device of claim 11, wherein if the address indicates a request to read the first sector, the controller is configured to ignore memory cells in the first sector that have a mapping value of a first binary value in a desired bit position and set the first sector of memory cells as the memory cells with a mapping value of a second binary mapping value in the desired bit position.

13. The memory device of claim 12, wherein the controller is configured to apply second and third reference voltages to the memory cells in the first sector and mark all memory cells in the first sector that are below the second reference voltage and above the third reference voltage with the first binary value.

14. The memory device of claim 13, wherein the second and third reference voltages are less than the first reference voltage.

15. The memory device of claim 13, wherein the controller is configured to output the first sector of data.

16. The memory device of claim 11, wherein if the controller determines that the read request is for the second sector, the controller is configured to ignore memory cells in the second sector with a mapping value a first binary value in a desired bit position and set memory cells of the second sector as the memory cells with a mapping value of a second binary value in the desired bit position.

17. The memory device of claim 16, wherein the controller is configured to apply fourth and fifth reference voltages to the memory cells in the second sector and mark all memory cells in the second sector below the fourth reference voltage and above the fifth reference voltage with the first binary value.

18. The memory device of claim 17, wherein the fourth and fifth reference voltages are greater than the first reference voltage.

19. The memory device of claim 18, wherein the controller is configured to output the second sector of data.

20. A method, comprising:
mapping levels of memory cells to bits such that a first half of the levels have a bit with a first binary value in a desired bit position and a second half of the levels have a bit with a second binary value in the desired bit position, the first half of the levels being a first group of consecutive levels, the second half of the levels being a second group of consecutive levels, the first binary value being opposite the second binary value, each of the memory cells being configured to store multiple bits of data;
generating a distribution for writing the data to the memory cells based on the mapping; and
writing the data to the memory cells based on the generated distribution by writing a first sector of bits of the data to memory cells where the generated distribution indicates that the desired bit position has the first binary value, and writing a second sector of bits of the data to memory cells where the generated distribution indicates that the desired bit position has the second binary value.

21. The memory device of claim 1,
wherein the desired bit position is a most significant bit position, and wherein the first sector of bits of the data and the second sector of bits of the data are sectors of a least significant bit page.
